(19) United States
(12) Patent Application Publication
(10) Pub. No.: US 2026/0322381 A1
(43) Pub. Date: Oct. 15, 2026

(54) Reduced Transistor Count Adiabatic Logic

(71) Applicant: Bitdeer, Inc., San Jose, CA (US)

(72) Inventor: Stephen M. Beccue, Salmon, ID (US)

(21) Appl. No.: 19/176,767

(22) Filed: Apr. 11, 2025

(51) Int. Cl. H03K 19/00

(52) U.S. Cl. CPC H03K 19/0019

(57) ABSTRACT

An adiabatic logic gate includes a pair of cross-coupled transistors of a first channel conduction type coupled to an output node and a complementary output node; an input logic block coupled to the output node including a plurality of transistors of a second channel conduction type; and a single transistor of the second channel conduction type having a gate coupled to the output node and a drain coupled to the complementary output node. Together, the single transistor and one of the transistors in the pair of cross-coupled transistors serve as an inverter during evaluation phases of a power clock, inverting, at the complementary output node, whatever binary output logic state is produced at the output node. An optional return-to-zero circuit serves to enhance charge recovery during charge recovery phases of the power clock, increase output voltage swing, and prevent pattern dependency from developing at the output node and/or complementary output node.

### BACKGROUND OF THE INVENTION

Adiabatic logic (also known as “charge recovery logic”) is a type of low-power electronic circuitry that can be used to overcome the energy efficiencies of conventional complementary metal-oxide-semiconductor (CMOS) logic. In general, the term “adiabatic” refers to a thermodynamic process in which no heat or energy is exchanged between the system and the external environment. Although the thermodynamical operation of an electronic circuit (the “system” in this case) can never be fully adiabatic, the term is nevertheless used in the electronics arts to emphasize the fact that in such ‘adiabatic’ circuits little heat is generated and undesirably lost to the external environment.

CMOS logic, in contrast, dissipates significantly more energy, and mostly during times it is switching between output logic states. For example, as the output Out(t) of a CMOS NOT gate 100 (i.e., inverter 100) (see FIG. 1) is being switched from a logic 0 to a logic 1 (in response to a logic 0 being applied to the NOT gate's 100's input In(t)), significant energy supplied from the CMOS NOT gate's 100's power supply is dissipated by the logic gate's p-channel (PMOS) transistor 102. In fact, assuming the CMOS NOT gate's 100's output load capacitance 106 is provided sufficient time to charge and discharge between successive changes in output logic states, it can be shown that only about one half the total energy supplied E_{supply}=C×V_{DD}² is actually transferred to the output load capacitance 106. The remaining half is undesirably dissipated in the form of heat by the on-resistance of PMOS transistor 102. (One half the supplied energy is also dissipated by the on-resistance of n-channel (NMOS) transistor 104 during times the output Out(t) of the logic gate 100 is being switched from a logic 1 to a logic 0.)

The significant power dissipated by the CMOS NOT gate 100 (and other types of CMOS logic gates (e.g., AND, OR, XOR, etc.)) is mostly due to the large currents i(t)=C×(dV/dt) that develop and flow in the gate's output network during times the gate is transitioning between output logic states. Adiabatic logic prevents these large currents from developing by ramping up the supply voltage during changes in output logic states, in other words, instead of allowing V_{DD} to be applied abruptly to the output network. By reducing the supply voltage slope dV/dt in this manner the maximum current flow through the output network is reduced and consequently so too then is the power dissipation i²R. The two different approaches: CMOS/abrupt and Adiabatic/ramped are contrasted in FIGS. 2A and 2B.

Applying Kirchhoff's voltage law to the adiabatic logic gate's output network (FIG. 2B) and with the knowledge that energy dissipation is ∫i²(t)Rdt, it can be shown that the energy dissipated by the adiabatic logic gate's output network during ramp-up: E_{diss,adiabatic}=(RC/τ)×CV_{DD}², where τ=dV₂/dt is the ramp-up time, R represents the on-resistance of the output network charging path, C represents the output load capacitance, and V_{DD} is the plateau voltage of Vᵣₐₘₚ. Accordingly, it is seen that the dynamic power dissipated by the adiabatic logic gate can be significantly reduced compared to the dynamic power dissipated by an equivalent-logic-function CMOS logic gate by simply increasing the ramp time τ=dV₂/dt relative to the RC time constant.

Various circuit topologies have been proposed over the years to implement adiabatic logic. FIG. 3 shows, for example, a schematic drawing of a 6-input Efficient Charge Recovery Logic (ECRL) AND gate 300. The 6-input ECRL AND gate 300 comprises cross-coupled PMOS transistors 302 and 304; six parallel-connected NMOS transistors (M1-M6) coupled between an output node OUT and V_{SS}; and six series-connected NMOS transistors (M7-M12) coupled between a complementary output node O̅U̅T̅ and V_{SS}. The gate of PMOS transistor 304 is connected to an output node OUT and the gate of PMOS transistor 302 is connected to a complementary output node O̅U̅T̅; the sources of both PMOS transistors 302 and 304 are connected to a power clock (PCLK) node 306, which receives a ramping power supply voltage PCLK; and the drains of PMOS transistors 302 and 304 are connected to the output and complementary output nodes OUT and O̅U̅T̅, respectively. Implementing the 6-input Boolean AND function F=A1·A2·A3·A4·A5·A6, the AND gate 300 produces a logic 1 on output node OUT only when all six input signals A1-A6 to NMOS transistors M7-M12 are at a logic 1 and all six input signal A̅1̅-A̅6̅ applied to NMOS transistors M1-M6 are at a logic 0. When this input condition is true, the process by which the AND gate 300 produces an output logic high (OUT=1) at its output node OUT proceeds as follows. With PCLK initially at zero and complementary output node O̅U̅T̅ pulled down to a logic 0 by NMOS transistors M7-M12, which are all on due to all six input signals A1-A6 being at a logic 1, PCLK begins ramping up. When PCLK rises above |V_{th,p}|, where V_{th,p} is the threshold voltage of PMOS transistor 302, PMOS transistor 302 turns on, allowing charge to flow into output load capacitor 308 in accordance with the ramp time τ=dV/dt. Output node OUT thus follows (i.e., tracks) PCLK during this evaluation phase of PCLK and ultimately produces a logic 1 when output load capacitor 308 has completed charging and PCLK has reached the plateau voltage V_{DD}. The process of producing the opposite output logic state (OUT=0) ensues similarly but with one or more of input signals A1-A6 to NMOS transistors M7-M12 set to a logic 0, one or more of input signals A̅1̅-A̅6̅ to NMOS transistors M1-M6 set to a logic 1, complementary output node O̅U̅T̅ tracking PCLK instead of output node OUT tracking PCLK, and output load capacitor 306 charging up instead of output load capacitor 308 charging up.

After the desired output logic state has been evaluated, it is held by AND gate 300 until, during a hold phase, the output logic state is read or captured as an input by a subsequent logic gate. PCLK is then ramped back down to V_{SS} during a charge recovery phase. Ramping PCLK down facilitates low power dissipation, just as ramping up the supply does. It further affords the ability to recover the charge that was stored on the output load capacitors 306 and 308 during evaluation phases and return that charge back to PCLK's energy reservoir, via PMOS transistor 302 and 304. Not all of the charge is able to be recycled back to PCLK, due to the non-zero threshold voltage V_{th,p} of PMOS transistors 302 and 304, each of which will turn off when PCLK<|V_{th,p}|. However, recycling the charge does make the adiabatic AND gate 300 more energy efficient than its CMOS logic counterpart.

The high energy efficiency of adiabatic logic gates is certainly desirable. However, there are various nonidealities that can render them less energy efficient than desired or intended. In particular, semiconductor processing variations can, and often do, result in physical and operational mismatches among the adiabatic logic gate's transistors and, consequently, an overall power dissipation above what ideal models predict. These inefficiencies are not easily avoided and are compounded by the fact that transistors do not operate as ideal switches—they have non-zero threshold voltages and they leak non-zero subthreshold currents. The additional power dissipation beyond what ideal models predict can be significant, especially for adiabatic logic gates that have a high valency (number of transistors that are connected in series and used to implement the gate's Boolean logic function), like the 6-input ECRL AND gate 300 described above, for example. That logic gate 300 has six NMOS transistors M7-M12 connected in series (valency=6), each presenting a resistance R and collectively dissipating 6×i²R. The additional power dissipation could be ameliorated by widening the widths of the logic-determining transistors. However, such an approach is undesirable since, among other problems, it would enlarge the integrated circuit die area occupied by the logic gate and increase the gate's output capacitance. The present invention addresses these and other related problems.

### BRIEF SUMMARY OF THE INVENTION

Adiabatic logic gates having a reduced number of transistors compared to conventional adiabatic logic gates are disclosed. An exemplary adiabatic logic gate, in accordance with one embodiment of the invention, includes a pair of cross-coupled transistors of a first channel conduction type coupled to an output node and a complementary output node; an input logic block coupled to the output node including a plurality of transistors of a second channel conduction type configured to implement a Boolean logic function; and a single transistor of the second channel conduction type having a gate coupled to the output node and a drain coupled to the complementary output node. Together, the single transistor and one of the transistors in the pair of cross-coupled transistors serve as an inverter during evaluation phases of a power clock, inverting, at the complementary output node, whatever binary output logic state the input logic block causes to be produced at the output node. The exemplary adiabatic logic gate is further optionally equipped with a return-to-zero (RTZ) circuit that is operable to enhance charge recovery during charge recovery phases of the power clock, increase output voltage swing, and prevent pattern dependency from developing at the output node and/or the complementary output node.

Further features and advantages of the invention, including a detailed description of the above-summarized and other exemplary embodiments of the invention, will now be described in detail with respect to the accompanying drawings, in which like reference numbers are used to indicate identical or functionally similar elements.

### BRIEF DESCRIPTION OF THE DRAWINGS

FIG. 1 is schematic drawing of a conventional CMOS NOT gate (i.e., inverter);

FIG. 2A is a drawing illustrating how in a conventional CMOS logic gate the DC power supply voltage V_{DD} is applied abruptly to the CMOS logic gate's output network during changes in output logic states;

FIG. 2B is a drawing illustrating how in an adiabatic logic gate the power supply voltage Vᵣₐₘₚ is ramped up so that large currents do not develop in the adiabatic logic gate's output network during changes in output logic states;

FIG. 3 is a schematic drawing of a six-input Enhanced Charge Recovery Logic (ECRL) AND gate;

FIG. 4 is a schematic drawing of a six-input adiabatic AND/NAND gate, according to an embodiment of the present invention;

FIG. 5A is a schematic drawing of a conventional ECRL OR/NOR gate;

FIG. 5B is a schematic drawing of an adiabatic OR/NOR gate, according to an embodiment of the present invention;

FIG. 6A is a schematic drawing of an ECRL XOR/XNOR gate;

FIG. 6B is a schematic drawing of an adiabatic XOR/XNOR gate, according to an embodiment of the present invention;

FIG. 7 is a schematic drawing of the adiabatic OR/NOR gate depicted in FIG. 5B but further augmented to include a return-to-zero (RTZ) circuit, in accordance with one embodiment of the present invention;

FIG. 8 is a schematic drawing of the adiabatic XOR/XNOR gate depicted in FIG. 6B but further augmented to include an RTZ circuit, in accordance with one embodiment of the present invention;

FIG. 9 is a schematic drawing of a generalized adiabatic logic circuit, according to one embodiment of the present invention; and

FIG. 10 is a schematic drawing of an alternative but functionally equivalent implementation of the six-input adiabatic AND/NAND gate depicted in FIG. 4 in which the pair of cross-coupled FETs is implemented using NMOS transistors instead of PMOS transistors and the input logic block is constructed from PMOS transistors instead of NMOS transistors, according to an embodiment of the present invention.

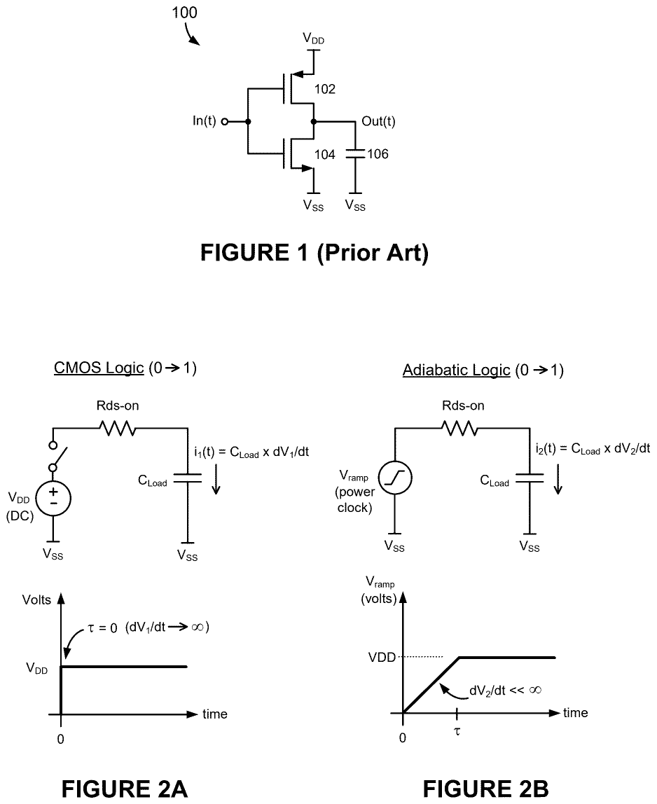

### DETAILED DESCRIPTION

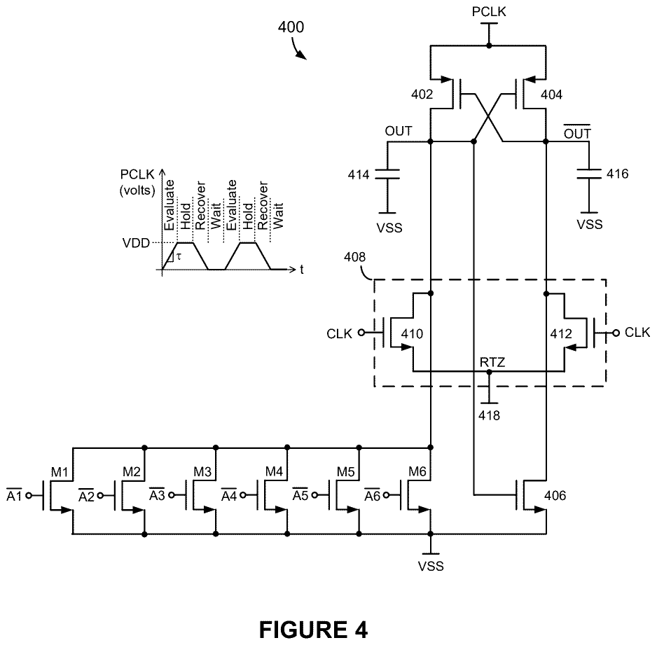

Referring to FIG. 4, there is shown a six-input adiabatic AND gate 400, according to one embodiment of the present invention. The six-input adiabatic AND gate 400 (referred to simply as “the AND gate 400” in the detailed description that follows), comprises: cross-coupled p-channel metal-oxide-semiconductor (PMOS) field-effect transistors 402 and 404; a logic block including six parallel-connected n-channel metal-oxide-semiconductor (NMOS) field-effect transistors (M1-M6) coupled between an output node OUT and a source supply voltage node V_{SS} (which, depending on the application, may be ground potential or some other supply voltage less than V_{DD}); a single (i.e., solitary or solo) NMOS transistor 406, separate from the six parallel-connected NMOS transistors M1-M6, having a gate coupled to the output node OUT, a drain coupled to a complementary output node O̅U̅T̅, and a source coupled to V_{SS}; and a return-to-zero (RTZ) circuit 408 including NMOS transistors 410 and 412. Though a six-input AND gate 400 is depicted in this example, those of ordinary skill in the art will appreciate and understand that the present invention is applicable to AND gates of any input number, in other words, not just six. Further, as will be explained in further detail below, the present invention is applicable to other logic gate types (e.g., OR, NOR, XOR, XNOR), in other words, not just AND gates, and is in fact applicable to any adiabatic logic circuit configured to implement essentially any Boolean logic function.

Before continuing it should be made clear what the term “adiabatic” means in the context of the present invention. In general, the term “adiabatic” refers to a thermodynamic process in which no heat or energy is exchanged between the system and the external environment. Although no electronic circuit (the “system” in this case) can be fully adiabatic, since any practical circuit must always dissipate some heat to the surrounding environment, it should be appreciated and understood, as it is appreciated understood by those of ordinary skill in the pertinent art, that the term “adiabatic” is nevertheless often and routinely used in the low-power electronic arts to refer to classes of electronic circuits and systems that use charge recovery logic (also referred to as “reversible logic”) to conserve energy. That same convention and meaning of the word “adiabatic” is used in the following detailed description of the present invention, and should also be recognized, appreciated, and understood when construing any appended claim that includes the word “adiabatic.”

The exemplary AND gate 400 produces an OUT=1 (O̅U̅T̅=0) only when all of input signals A̅1̅-A̅6̅ applied to NMOS transistors M1-M6 are at an input logic low (i.e., logic 0), resulting in all of NMOS transistors M1-M6 being turned off. When this input condition is present, the process by which an output logic high (OUT=1) is evaluated at output node OUT proceeds as follows. Note that both the output node OUT and complementary output node O̅U̅T̅ are both initially at a logic 0, their respective output load capacitors 414 and 416 having been discharged and recycled back to PCLK during a prior charge recovery phase and with the aid of RTZ circuit 408. PCLK begins ramping up during this evaluation phase, at rate τ=dV/dt. Upon PCLK ramping up to a voltage sufficient to turn PMOS transistor 402 on (i.e., when PCLK>|V_{th,p}|, where V_{th,p} is the threshold voltage of PMOS transistor 402), the voltage on output node OUT begins following/tracking PCLK. This allows output load capacitor 414 to charge up and the voltage at output node OUT to ultimately rise to the final desired output logic high (OUT=1). Meanwhile, also as PCLK begins ramping up, the voltage on output node OUT quickly surpasses the threshold voltage V_{th,n} of NMOS transistor 406, causing NMOS transistor 406 to turn on, pull complementary output node O̅U̅T̅ down to V_{SS}, and thereby ensure that complementary output node O̅U̅T̅ is evaluated and held at the desired final output logic low (O̅U̅T̅=0).

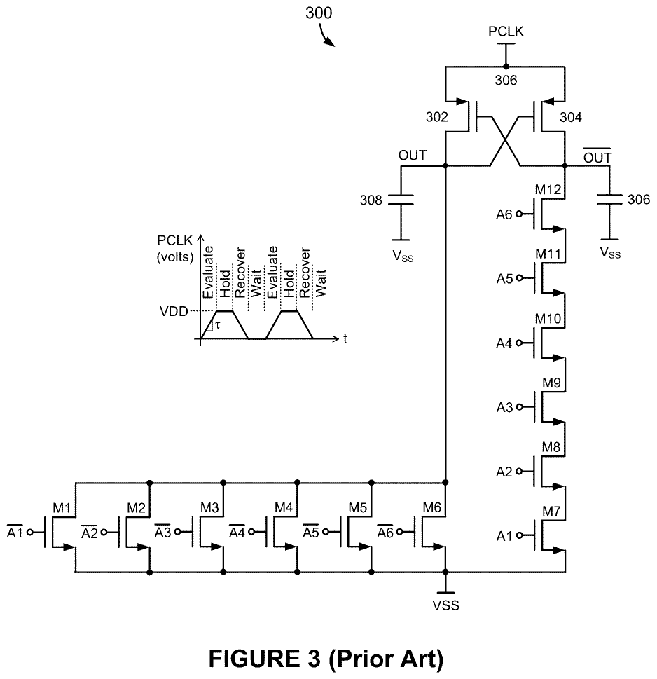

In a subsequent evaluation phase, during which one or more input signals A̅1̅-A̅6̅ to NMOS transistors M1-M6 is/are set to an input logic 1 and AND gate 400 is directed to produce an OUT=0 (i.e., the opposite output logic state from that just described above), NMOS transistor 406 remains off and output load capacitor 416 charges via PMOS transistor 404, until complementary output node O̅U̅T̅ reaches the final desired output logic high (O̅U̅T̅=1). It is seen, therefore, that, together, PMOS transistor 404 and NMOS transistor 406 serve as an inverter during evaluation phases of PCLK, inverting whatever binary output logic state the gate produces at output node OUT at complementary output node O̅U̅T̅. Advantageously, during evaluation phases in which complementary output node O̅U̅T̅=0, only the single NMOS transistor 406 is needed to pull the complementary output node O̅U̅T̅ down and then hold it at a logic 0 (compared to the six series-connected NMOS transistors M7-M12 that are required to perform the same function in the ECRL AND logic gate 300 discussed above in reference to FIG. 3). The AND gate 400 is therefore a more compact and energy-efficient design compared to the conventional ECRL AND logic gate 300 described above in reference to FIG. 3. In addition to realizing a lower power dissipation, in view of having only one Rds-on versus 6×Rds-on, fan-in and wiring are also reduced.

It should be noted that during the evaluation and hold phases of PCLK, AND gate 400 not only produces the Boolean AND function F=A1·A2·A3·A4·A5·A6 at output node OUT, it also produces its complement F̅=A̅1̅·̅A̅2̅·̅A̅3̅·̅A̅4̅·̅A̅5̅·̅A̅6̅ at complementary output node O̅U̅T̅. For this reason, AND gate 400 may be alternatively referred to as AND/NAND gate 400.

It should also be noted that an equivalent AND/NAND gate 400 is produced if the OUT and O̅U̅T̅ terminals are flipped from how shown in FIG. 4 and all input signals to the AND/AND gate 400 are inverted. A similar equivalency applies to all other logic gates of the present invention disclosed herein. Accordingly, the appended claims should be deemed to encompass all of these equivalents.

The RTZ circuit 408 in AND/NAND gate 400 serves to return both the output node OUT and complementary output node O̅U̅T̅ to zero after the outputs have been read or conveyed to a subsequent logic gate during the hold phase of PCLK. Returning the two nodes to zero increases signal swing and prepares the gate for the next evaluation phase. Returning output node OUT and complementary output node O̅U̅T̅ to zero also provides the benefit of removing any pattern dependency that might otherwise develop at output node OUT and/or complementary output node O̅U̅T̅. The RTZ node 418 can be connected to PCLK or V_{SS}. Connecting RTZ node 418 to PCLK is preferred since it enhances charge recovery during the charge recovery phase (when PCLK is ramped down), making the logic gate more energy efficient, but connecting RTZ node 418 to V_{SS} may be done instead for simplicity. If tied to PCLK, CLK2, which control RTZ NMOS transistors 410 and 412, is made active high when PCLK is low, so that the RTZ circuit 408 is only operational during wait phases of PCLK.

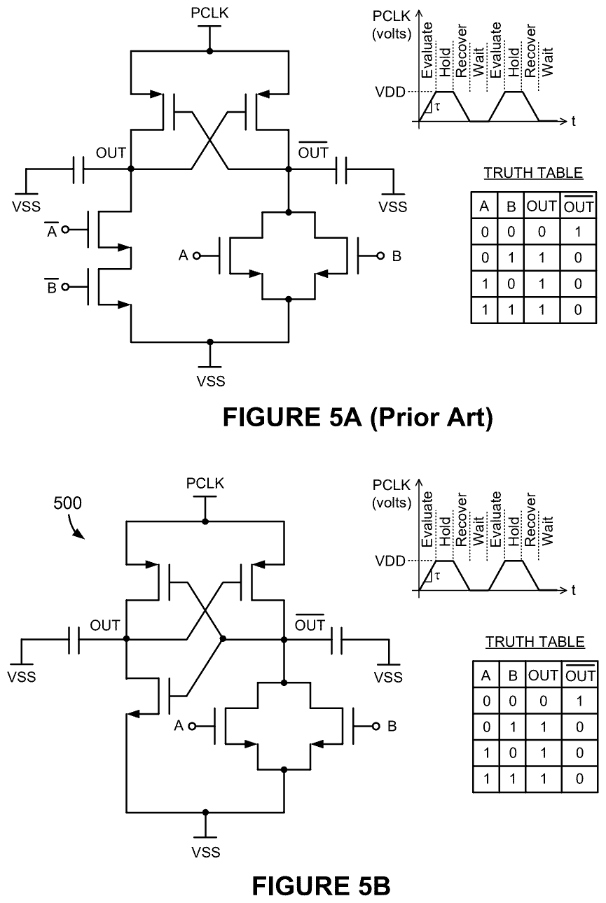

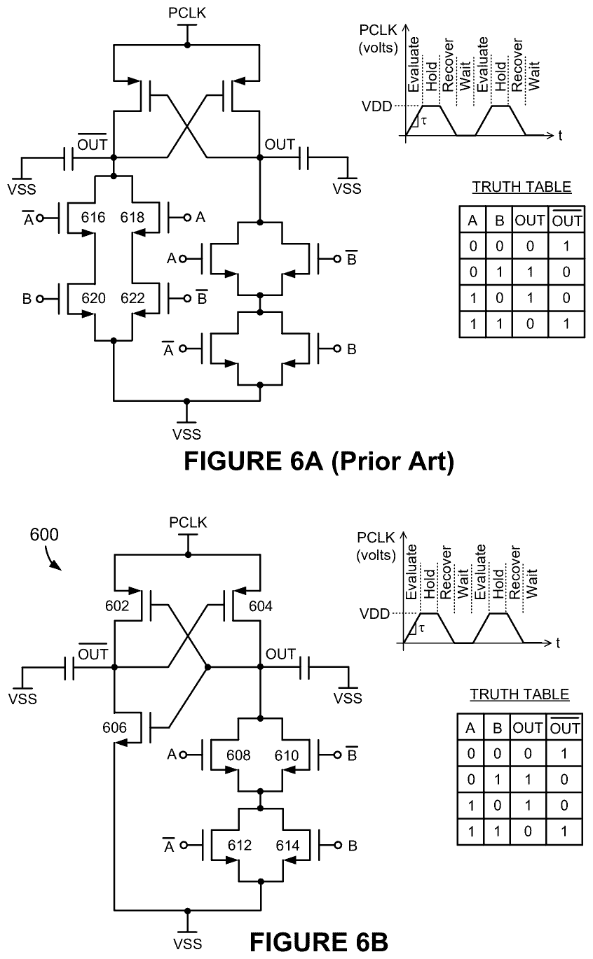

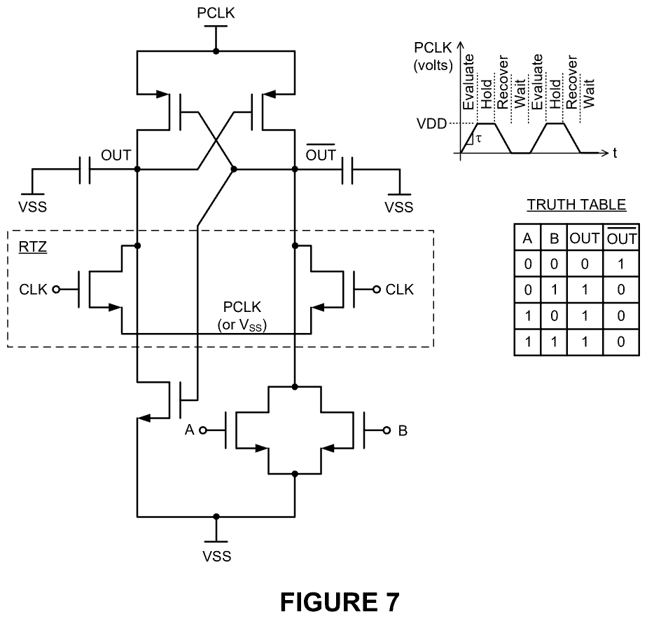

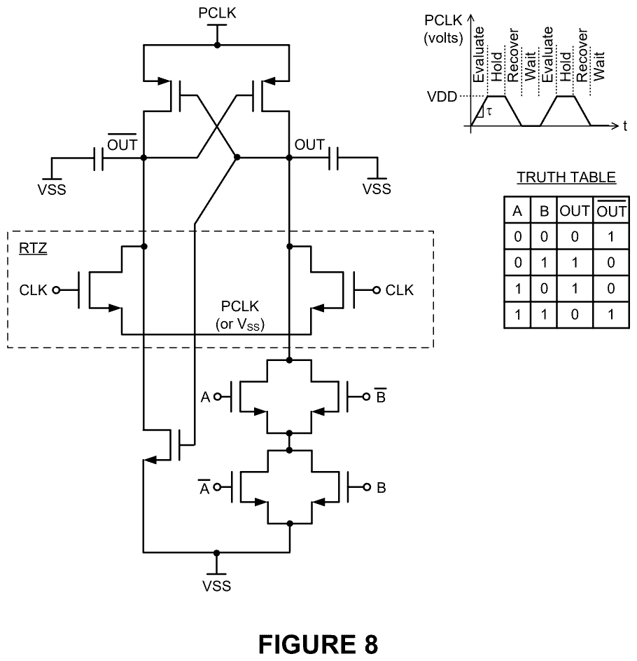

The fundamental principles of the present invention described above are applicable to other basic types of adiabatic logic gates. FIGS. 5A and 5B illustrate how the conventional ECRL OR/NOR gate depicted in FIG. 5A can be modified to produce the adiabatic OR/NOR gate 500 depicted in FIG. 5B, which is another exemplary embodiment of the present invention, and FIGS. 6A and 6B illustrate how the conventional ECRL XOR gate depicted in FIG. 6A can be modified to produce the adiabatic XOR/XNOR gate 600 depicted 6B, which is yet another exemplary embodiment of the present invention. FIGS. 7 and 8 illustrate how both the adiabatic OR/NOR gate 500 depicted in FIG. 5B and the adiabatic XOR/XNOR gate 600 depicted in FIG. 6B can be further modified to include RTZ circuits, similar to the RTZ circuit 408 employed by the AND/NAND gate 400 described above in reference to FIG. 4.

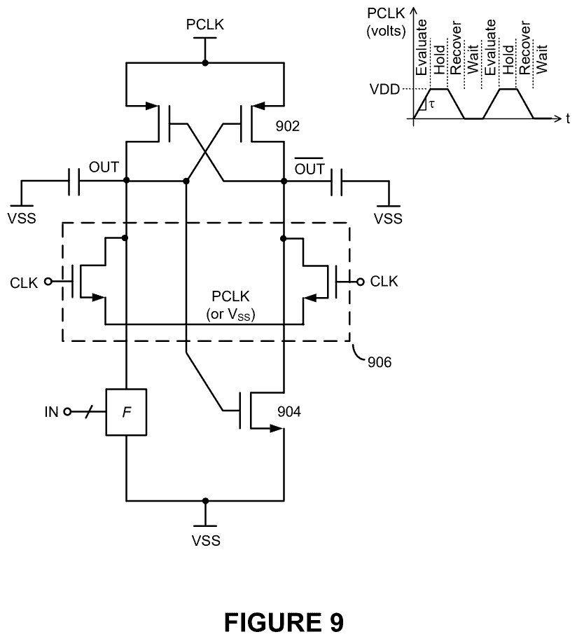

Not only do the fundamental principles of the present invention extend to basic Boolean logic gates (AND, NAND, OR, NOR, XOR, XNOR), they extend, even more generally, to any adiabatic logic circuit configured to perform any conceivable Boolean logic function F. This generalization is illustrated in FIG. 9, where PMOS transistor 902 and single NMOS transistor 904 serve as the inverter, inverting at complementary output node O̅U̅T̅ whatever binary output logic state the input logic block F causes to be produced at output node OUT during the evaluation and hold phases of the power clock PCLK, and the RTZ circuit 906 performs substantially the same operations as the RTZ circuits do in the various embodiments of the present invention described above in reference to FIGS. 4, 7 and 8.

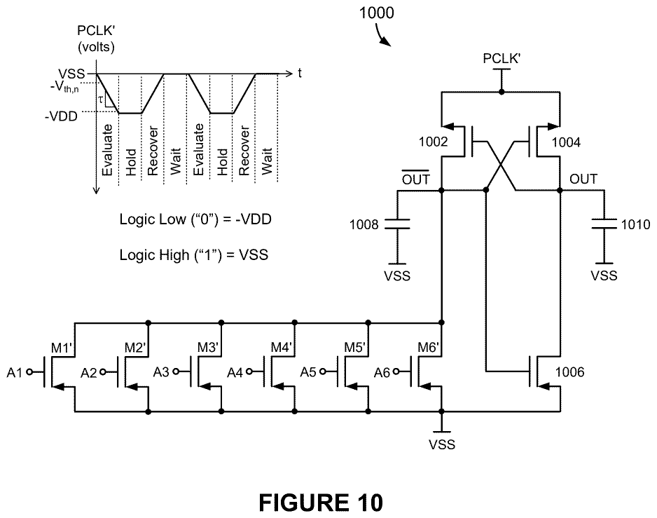

Finally, it should be mentioned that for every one of the various adiabatic logic gates described above there is an equivalent adiabatic logic gate that can be made by: 1) substituting each NMOS transistor for an PMOS transistor; 2) substituting each NMOS transistor for a PMOS transistor; and 3) controlling the resulting, modified adiabatic logic gates using a modified power clock PCLK′ that oscillates between VSS (ground) and −VDD. FIG. 10 shows, for example, a schematic drawing of an alternative, but functionally equivalent, six-input adiabatic AND/NAND logic gate 1000 in which a pair of cross-coupled NMOS transistors 1002 and 1004 is used instead of a pair of cross-coupled PMOS transistors 402 and 404, and in which the input logic block comprises six PMOS transistors M1′-M6′ instead of the six NMOS transistors M1-M6. (Compare FIGS. 4 and 10.)

The alternative six-input adiabatic AND/NAND logic gate 1000 employs a single (i.e., solitary or solo) PMOS transistor 1006 to invert, at output node OUT, whatever binary output logic state is produced at complementary output node O̅U̅T̅, thus providing the same benefit as the six-input adiabatic AND/NAND logic gate 400—that is eliminating the need for the six series-connected NMOS transistors M7-M12 that the conventional ECRL AND logic gate 300 depicted in FIG. 3 requires to perform the identical AND/NAND logic function.

The equivalent adiabatic AND/NAND logic gate 1000 produces an OUT=1 (O̅U̅T̅=0) only when all input signals A1-A6 are at an input logic high (VSS), resulting in all PMOS transistors M1′-M6′ being off. When this input condition is present, the process by which the equivalent adiabatic AND/NAND logic gate 1000 evaluates an output logic high (VSS) at output node OUT and an output logic low (−VDD) at complementary output node O̅U̅T̅ proceeds as follows. (Note that both output node OUT and complementary output node O̅U̅T̅ are both initially reset to VSS just before each evaluation phase begins, their respective output load capacitors 1008 and 1010 having been discharged and recycled back to PCLK′ during a prior charge recovery phase.) As PCLK′ begins ramping down from VSS to −VDD, NMOS transistor 1002 soon turns on, once (VSS−PCLK′)>V_{th,n}, where V_{th,n} is the threshold voltage of NMOS transistors 1002 and 1004, allowing the voltage on complementary output node O̅U̅T̅ to begin tracking PCLK′ and ultimately reaching the final output logic low of −VDD (OUT =0). Meanwhile, also as PCLK′ begins ramping down, the voltage on complementary output node O̅U̅T̅ quickly lowers to a value sufficient to turn PMOS transistor 1006 on, causing PMOS transistor 1006 to pull output node OUT up to VSS and thereby ensure that output node OUT is evaluated and held at the desired final output logic high (OUT=1).

In a subsequent evaluation phase, during which one or more of input signals A1-A6 is set to an input logic low (−VDD) and one or more of PMOS transistors M1′-M6′ is/are turned on, the adiabatic AND/NAND logic gate 1000 produces an OUT=0, in other words, the opposite output logic state from that just described above. Specifically, as PCLK′ begins ramping down from VSS to −VDD, NMOS transistor 1004 soon turns on, once (VSS−PCLK′)>V_{th,n}, and the voltage on output node OUT begins tracking PCLK′, ultimately reaching the final desired output logic low of −VDD (OUT=0). Meanwhile, PMOS transistor 1006 remains off, ensuring that output node OUT is evaluated and held at the desired final output logic low (OUT=0).

While various embodiments of the present invention have been described, they have been presented by way of example and not limitation. It will be apparent to persons skilled in the relevant art that various changes in form and detail may be made to the exemplary embodiments without departing from the true spirit and scope of the invention. Accordingly, the scope of the invention should not be limited by the specifics of the exemplary embodiments but, instead, should be determined by the appended claims, including the full scope of equivalents to which such claims are entitled.

1. An adiabatic logic circuit, comprising:
a pair of cross-coupled transistors of a first channel conduction type coupled to an output node and a complementary output node and having a power clock node configured to receive a power clock;
an input logic block coupled to the output node including a plurality of transistors of a second channel conduction type, the plurality of transistors configured to implement a Boolean logic function that determines whether the output node during evaluation phases of the power clock remains at a first binary output logic state or is to change to a second binary output logic state; and
a single transistor of the second channel conduction type having a gate coupled to the output node and a drain coupled to the complementary output node;
wherein, together, the single transistor and one of the transistors from the pair of cross-coupled transistors serve as an inverter during evaluation and hold phases of the power clock, inverting, at the complementary output node, whatever binary output logic state is produced at the output node.

2. The adiabatic logic circuit of claim 1, further comprising a return-to-zero (RTZ) circuit coupled to the output node and the complementary output node, the RTZ circuit operable to increase an output voltage swing at both the output node and the complementary output node.

3. The adiabatic logic circuit of claim 2, wherein the RTZ circuit is further operable to reduce pattern dependency at both the output node and the complementary output node.

4. The adiabatic logic circuit of claim 2, wherein the RTZ circuit includes an RTZ node that is coupled to the power clock node, and the RTZ circuit is further operable to enhance charge recovered from an output node load capacitance during a recovery phase of the power clock PCLK.

5. A method of changing an output logic state in an adiabatic logic circuit during an evaluation phase, comprising:
applying a plurality of input logic values to a plurality of transistors in an input logic block of an adiabatic logic circuit;
ramping a voltage on an output node in the adiabatic logic circuit up or down to a first binary output logic state in response to an output logic result produced by the input logic block; and
using only a single transistor, pulling up or down a complementary output node in the adiabatic logic circuit to a second binary output logic state, the single transistor having a drain coupled to a complementary output node in the adiabatic logic circuit and a gate coupled to the output node.

6. The method of claim 5, further comprising, during a subsequent charge recovery phase, recovering charge that was supplied by the power clock during the evaluation phase.

7. The method of claim 6, further comprising enhancing charge recovery during the charge recovery phase using a return-to-zero (RTZ) circuit coupled to the output node and complementary output node of the adiabatic logic gate.

8. The method of claim 7, wherein the RTZ circuit is further operable to reduce pattern dependency at both the output node and complementary output node.

9. An adiabatic AND/NAND gate, comprising:
first and second cross-coupled p-channel metal-oxide-semiconductor (PMOS) transistors with the sources of both the first and second PMOS transistors coupled to a power clock node, the drain of the first PMOS transistor and gate of the second PMOS transistor coupled to an output node, and the drain of the second PMOS transistor and gate of the first PMOS transistor coupled to a complementary output node;
a NAND logic block coupled between the output node and a source supply voltage node V_{SS}; and
an n-channel metal-oxide-semiconductor (NMOS) transistor having a drain coupled to the complementary output node, a gate coupled to the output node, and a source coupled to the source supply voltage node V_{SS};
wherein during an evaluation phase of the power clock PCLK, together, the NMOS transistor and the second PMOS transistor serve as an inverter, inverting whatever output logic state is produced at the output node at the complementary output node.

10. The adiabatic AND/NAND gate of claim 9, further comprising a return-to-zero (RTZ) circuit coupled to the output node and the complementary output node, the RTZ circuit operable to increase an output voltage swing at both the output node and the complementary output node.

11. The adiabatic AND/NAND gate of claim 10, wherein the RTZ circuit is further operable to reduce pattern dependency at both the output node and the complementary output node.

12. The adiabatic AND/NAND gate of claim 10, wherein the RTZ circuit is coupled to the power clock node and, and the RTZ circuit is further operable to enhance charge recovered from an output node load capacitance during a recovery phase of the power clock PCLK.

13. An adiabatic OR/NOR gate, comprising:
first and second cross-coupled p-channel metal-oxide-semiconductor (PMOS) transistors with the sources of both the first and second PMOS transistors coupled to a power clock node, the drain of the first PMOS transistor and gate of the second PMOS transistor coupled to an output node, and the drain of the second PMOS transistor and gate of the first PMOS transistor coupled to a complementary output node;
an OR logic block coupled between the complementary output node and a source supply voltage node V_{SS}; and
an n-channel metal-oxide-semiconductor (NMOS) transistor having a drain coupled to the output node, a gate coupled to the complementary output node, and a source coupled to the source supply voltage node V_{SS};
wherein during an evaluation phase of the power clock PCLK, together, the NMOS transistor and the first PMOS transistor serve as an inverter, inverting whatever output logic state is produced at the complementary output node at output node.

14. The adiabatic OR/NOR gate of claim 13, further comprising a return-to-zero (RTZ) circuit coupled to the output node and the complementary output node, the RTZ circuit operable to increase an output voltage swing at both the output node and the complementary output node.

15. The adiabatic OR/NOR gate of claim 14, wherein the RTZ circuit is further operable to reduce pattern dependency at both the output node and the complementary output node.

16. The adiabatic OR/NOR gate of claim 14, wherein the RTZ circuit is coupled to the power clock node, and the RTZ circuit is further operable to enhance charge recovered from an output node load capacitance during a recovery phase of the power clock PCLK.

17. An adiabatic XOR/XNOR gate, comprising:
first and second cross-coupled p-channel metal-oxide-semiconductor (PMOS) transistors with the sources of both the first and second PMOS transistors coupled to a power clock node, the drain of the first PMOS transistor and gate of the second PMOS transistor coupled to an output node, and the drain of the second PMOS transistor and gate of the first PMOS transistor coupled to a complementary output node;
an XOR logic block coupled between an output node and a source supply voltage node V_{SS}; and
an n-channel metal-oxide-semiconductor (NMOS) transistor having a drain coupled to the complementary output node, a gate coupled to the output node, and a source coupled to the source supply voltage node V_{SS};
wherein during an evaluation phase of the power clock PCLK, together, the NMOS transistor and the second PMOS transistor serve as an inverter, inverting whatever output logic state is produced at the output node at the complementary output node.

18. The adiabatic XOR/XNOR gate of claim 17, further comprising a return-to-zero (RTZ) circuit coupled to the output node and the complementary output node, the RTZ circuit operable to increase an output voltage swing at both the output node and the complementary output node.

19. The adiabatic XOR/XNOR gate of claim 18, wherein the RTZ circuit is further operable to reduce pattern dependency at both the output node and the complementary output node.

20. The adiabatic XOR/XNOR gate of claim 18, wherein the RTZ circuit is coupled to the power clock node, and the RTZ circuit is further operable to enhance charge recovered from an output node load capacitance during a recovery phase of the power clock PCLK.
